(19) United States
(12) Patent Application Publication
(10) Pub. No.: US 2025/0248014 A1
(43) Pub. Date: Jul. 31, 2025

(54) ELECTRONIC DEVICE

(71) Applicant: Panasonic Intellectual Property Management Co., Ltd., Osaka (JP)

(72) Inventor: Akihiro OKI, Osaka (JP)

(73) Assignee: Panasonic Intellectual Property Management Co., Ltd., Osaka (JP)

(21) Appl. No.: 19/027,292

(22) Filed: Jan. 17, 2025

(30) Foreign Application Priority Data
Jan. 25, 2024 (JP) 2024-009534

(51) Int. Cl. H05K 9/00

(52) U.S. Cl. CPC H05K 9/0007

(57) ABSTRACT

An electronic device includes: a non-conductive external member; a non-conductive internal member disposed on an inner side of the external member; a conductive fixing member that is exposed to an outside at an outer surface of the external member and fixes the external member to the internal member in a first direction; a conductive elastic member in elastic contact with the fixing member in the first direction; and a static eliminating member that is electrically connected to the elastic member and eliminates electricity of the fixing member via the elastic member.

### BACKGROUND

### Technical Field

The present disclosure relates to an electronic device.

### Description of the Related Art

Conventionally, various countermeasures have been taken against electrostatic discharge via fixing screws (fixing members), in electronic devices (see, for example, JP 2003-243855 A).

### SUMMARY

There is a case where a fixing screw made of a conductive material is used to fix a plurality of members made of a non-conductive material such as a resin material, to each other. That is, the fixing screw may not be in contact with a conductive material, for example, a conductive member made of a metal material. In such a case, when an object storing static electricity, such as a finger of a person, comes into contact with the fixing screw, static electricity may be discharged from the fixing screw to a nearby conductive member. For example, when an electronic component such as a circuit board is present near the fixing screw, the electronic component may be damaged by electrostatic discharge from the fixing screw.

Therefore, an object of the present disclosure is to suppress electrostatic discharge from a fixing member in an electronic device including the fixing member that is used without having a contact with a conductive member.

In order to solve the above problem, according to an aspect of the present disclosure, an electronic device is provided that includes:
a non-conductive external member;
a non-conductive internal member disposed on an inner side of the external member;
a conductive fixing member that is exposed to an outside at an outer surface of the external member and fixes the external member to the internal member in a first direction;
a conductive elastic member in elastic contact with the fixing member in the first direction; and
a static eliminating member that is electrically connected to the elastic member and eliminates electricity of the fixing member via the elastic member.

According to the present disclosure, in an electronic device including a fixing member that is used without having a contact with a conductive member, electrostatic discharge from the fixing member can be suppressed.

### BRIEF DESCRIPTION OF DRAWINGS

FIG. 1 is a perspective view of an electronic device according to an embodiment of the present disclosure;

FIG. 2 is an exploded perspective view of a part of the electronic device;

FIG. 3 is a partial cross-sectional view of a part of the electronic device taken along line A-A illustrated in FIG. 1;

FIG. 4 is a perspective view illustrating a periphery of a through hole of an external member before a fixing screw is attached;

FIG. 5 is a front view illustrating a periphery of the through hole of the external member before the fixing screw is attached;

FIG. 6 is a perspective view illustrating attachment of an elastic member to the external member; and

FIG. 7 is a partial cross-sectional view of a part of an electronic device according to another embodiment.

### DETAILED DESCRIPTION

Hereinafter, embodiments will be described in detail with reference to the drawings as appropriate. However, unnecessarily detailed description may be omitted. For example, a detailed description of a well-known matter and a repeated description of substantially the same configuration may be omitted. This is to avoid unnecessary redundancy of the following description and to facilitate understanding of those skilled in the art.

Note that the inventor(s) provides the accompanying drawings and the following description in order for those skilled in the art to fully understand the present disclosure, and does not intend to limit the subject matter described in the claims by the accompanying drawings and the following description.

Hereinafter, an electronic device according to an embodiment of the present disclosure will be described with reference to the drawings.

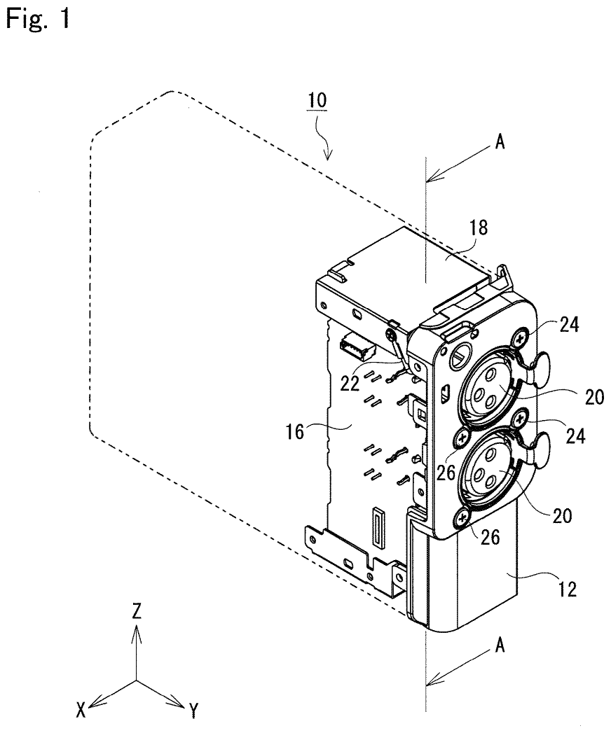

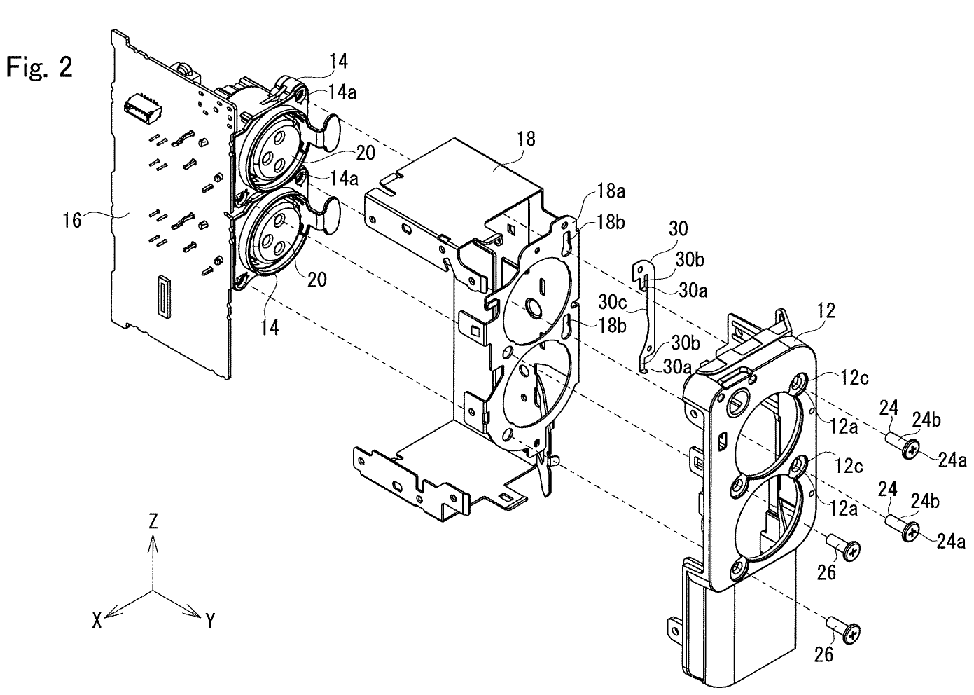

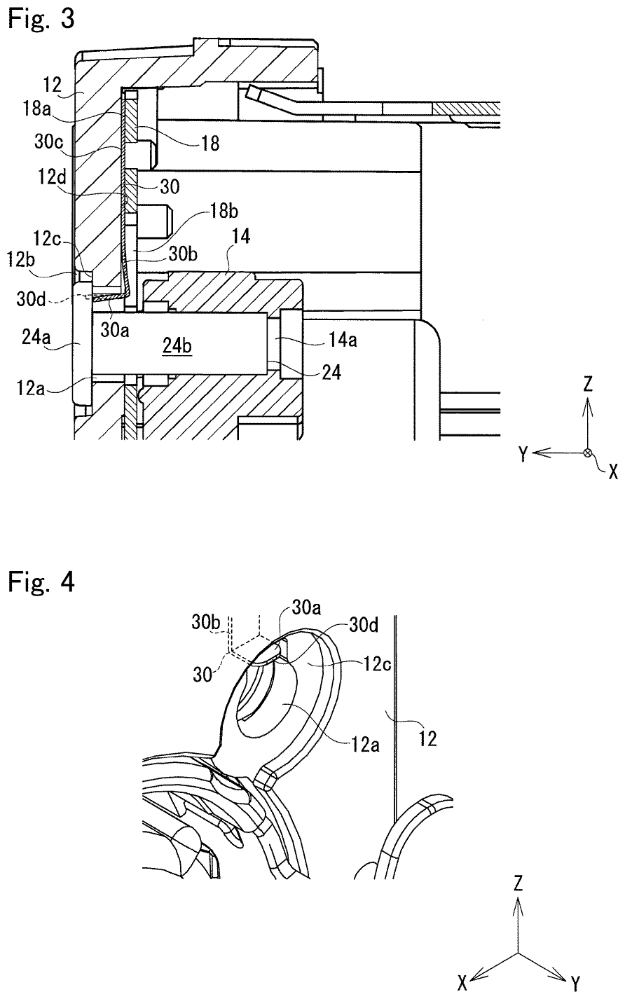

FIG. 1 is a perspective view of the electronic device according to the embodiment of the present disclosure. Note that, in FIG. 1, only a part is illustrated, and the remaining part is not illustrated. In addition, FIG. 2 is an exploded perspective view of a part of the electronic device. Furthermore, FIG. 3 is a partial cross-sectional view of a part of the electronic device taken along line A-A illustrated in FIG. 1. Note that the X-Y-Z orthogonal coordinate system illustrated in the drawings is for facilitating understanding of the embodiment of the present disclosure, and does not limit the embodiment of the present disclosure.

As illustrated in FIGS. 1 and 2, an electronic device 10 according to the present embodiment includes an external member 12 including a part of an outer surface of the electronic device 10, an internal member 14 disposed inside the electronic device 10, a circuit board 16 that is an electronic component disposed inside the electronic device 10, and a frame 18 that supports the circuit board 16.

The external member 12 and the internal member 14 are non-conductive. In the present embodiment, the external member 12 and the internal member 14 are made of a non-conductive material such as a resin material. Note that the internal member 14 is a casing of a connector 20 and is attached to the circuit board 16.

The circuit board 16 is an electronic component in which the connector 20 is mounted, and is disposed inside the electronic device 10 and supported by the frame 18.

The frame 18 is a member made of a conductive material such as a metal material, and is disposed inside the electronic device 10 to support the circuit board 16. In addition, the frame 18 is electrically connected to a ground potential part of the circuit board 16 via a lead wire 22. Therefore, the frame 18 has a ground potential.

In the present embodiment, the external member 12 is fixed to the internal member 14 in a first direction (Y-axis direction) via fixing screws 24 and 26.

The fixing screw 24 is made of a conductive material such as a metal material, and includes a head portion 24a and a male screw portion 24b extending from the head portion 24a.

In order to fix the external member 12 to the internal member 14 via the fixing screw 24, in the present embodiment, the external member 12 includes a through hole 12a and the internal member 14 includes a female screw hole 14a. The male screw portion 24b of the fixing screw 24 passes through the through hole 12a of the external member 12 and engages with the female screw hole 14a of the internal member 14. Note that, in the present embodiment, a counterbore 12b in which the head portion 24a of the fixing screw 24 is accommodated is formed in the external member 12.

Similarly to the fixing screw 24, the fixing screw 26 also fixes the external member 12 to the internal member 14.

Further features of the electronic device 10 according to the embodiment of the present disclosure will be described below.

As described above, and as illustrated in FIG. 3, the conductive fixing screw 24 is in contact with the non-conductive external member 12 and internal member 14, but is not in contact with a conductive member such as the frame 18. Therefore, when an object storing static electricity, such as a finger of a person, comes into contact with the head portion 24a of the fixing screw 24 exposed at the outer surface of external member 12, static electricity may be discharged from the fixing screw 24 to the nearby circuit board 16. That is, there is a possibility that a spark occurs between the fixing screw 24 and the circuit board 16. As a result, for example, there is a possibility that a semiconductor element mounted on the circuit board 16 is damaged or malfunctions.

In order to suppress electrostatic discharge from the fixing screw 24 to the circuit board 16, the fixing screw 24 is electrically connected to the frame 18 via a conductive elastic member 30, as illustrated in FIGS. 2 and 3.

The elastic member 30 is a member made of a conductive material such as a metal thin plate, and is in elastic contact with the fixing screw 24 in a fixing direction (first direction (Y-axis direction)) of the external member 12 to the internal member 14. Note that the first direction is a penetrating direction of the through hole 12a of the external member 12, and is also an extending direction of the female screw hole 14a of the internal member 14, that is, an extending direction of the male screw portion 24b of the fixing screw 24. The term “elastic contact” means a contact with an object by a restoring force of an elastically deformed elastic member.

In the present embodiment, as illustrated in FIG. 3, the elastic member 30 comes into elastic contact with a rear side part of the head portion 24a of the fixing screw 24 from the inner side of the electronic device 10 in the first direction (Y-axis direction). In order to do so, the elastic member 30 enters the through hole 12a of the external member 12.

Specifically, in the present embodiment, the elastic member 30 includes a contact end portion 30a that comes into contact with the head portion 24a of the fixing screw 24, a cantilever portion 30b that supports the contact end portion 30a, and a base portion 30c that supports the cantilever portion 30b in a cantilever manner.

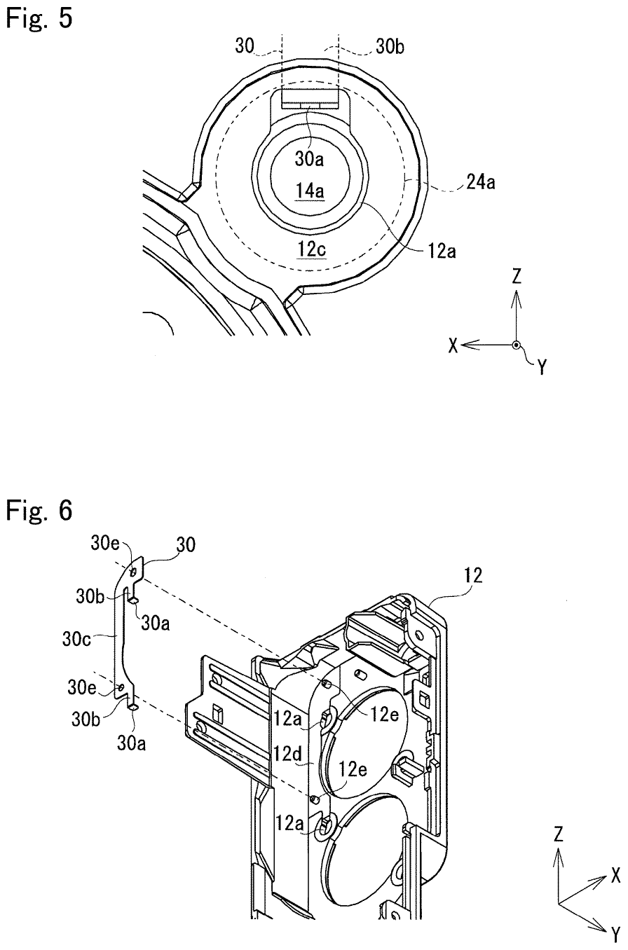

FIGS. 4 and 5 are a perspective view and a front view illustrating a periphery of the through hole of the external member before the fixing screw is attached. In addition, FIG. 6 is a perspective view illustrating attachment of the elastic member to the external member.

In the elastic member 30, as illustrated in FIGS. 3 and 4, the contact end portion 30a is a part that extends in the first direction (Y-axis direction) and passes through the through hole 12a of the external member 12. As indicated by a broken line in FIG. 3, when the fixing screw 24 is not attached, one end 30d (one end in the extending direction) of the contact end portion 30a goes beyond a bottom surface 12c of the counterbore 12b of the external member 12.

Note that, as illustrated in FIG. 5, the through hole 12a of the external member 12 through which the contact end portion 30a and the male screw portion 24b of the fixing screw 24 pass has a keyhole shape so that the contact end portion 30a and the male screw portion 24b do not come into contact with each other. That is, the through hole 12a is a penetration hole formed by integrating a penetration hole having a circular cross section through which the male screw portion 24b passes and a penetration hole having a rectangular cross section through which the contact end portion 30a passes. Alternatively, the penetration hole through which the male screw portion 24b passes and the penetration hole through which the contact end portion 30a passes may be formed in the external member 12 in a state of being separated from each other.

In the elastic member 30, as illustrated in FIG. 4, the cantilever portion 30b is a belt-like part that is bendable and deformable in the first direction (Y-axis direction), that is, a part thin in the first direction. In addition, as illustrated in FIG. 3, the cantilever portion 30b extends in a second direction (Z-axis direction) intersecting the first direction from the other end (the other end in the extending direction) of the contact end portion 30a. Note that, in the present embodiment, the extending length (size in the Z-axis direction) of the cantilever portion 30b is larger than the extending length (size in the Y-axis direction) of the contact end portion 30a.

In the elastic member 30, the base portion 30c is a part that supports, in a cantilever manner, the end of the cantilever portion 30b which is on the side opposite to the end where the contact end portion 30a is provided. The base portion 30c is also a part in contact with the frame 18, that is, a part of the elastic member 30 electrically connected to the frame 18.

As illustrated in FIG. 6, in the present embodiment, the base portion 30c of the elastic member 30 is attached to the external member 12 in a positioned state. Specifically, a seating surface 12d on which the cantilever portion 30b and the base portion 30c of the elastic member 30 are seated is formed on an inner surface of the external member 12. In addition, the seating surface 12d is provided with two positioning pins 12e. Two positioning holes 30e engaged with the respective positioning pins 12e are formed in the base portion 30c of the elastic member 30.

As illustrated in FIG. 3, when the external member 12 is fixed to the internal member 14 in the first direction (Y-axis direction) via the fixing screw 24, the base portion 30c of the elastic member 30 is sandwiched between the seating surface 12d of the external member 12 and the frame 18 in the first direction. That is, as illustrated in FIG. 2, a surface 18a, which is facing the external member 12 in the first direction in the frame 18 that supports the circuit board 16 provided with the internal member 14, comes into contact with the base portion 30c of the elastic member 30.

Note that, the surface 18a of the frame 18 is not in contact with the cantilever portion 30b of the elastic member 30. A penetration hole 18b for avoiding a contact with the cantilever portion 30b is formed on the surface 18a of the frame 18. As illustrated in FIG. 3, when the cantilever portion 30b is bent and deformed, the cantilever portion 30b enters the penetration hole 18b. In addition, the male screw portion 24b of the fixing screw 24 passes through the penetration hole 18b.

Such an elastic member 30 causes the electrical connection between the fixing screw 24 and the frame 18 to be maintained. Specifically, as illustrated in FIG. 3, when the head portion 24a of the fixing screw 24 is seated on the bottom surface 12c of the counterbore 12b of the external member 12, the one end 30d of the contact end portion 30a of the elastic member 30 protruding from the bottom surface 12c is pushed by the head portion 24a of the fixing screw 24 and retreats into the through hole 12a of the external member 12. Due to this retraction, the cantilever portion 30b of the elastic member 30 is bent and deformed, and is separated from the seating surface 12d of the external member 12.

While the fixing screw 24 fixes the external member 12 to the internal member 14, that is, while the head portion 24a of the fixing screw 24 continues to be seated on the bottom surface 12c of the counterbore 12b, the cantilever portion 30b continues to be bent and deformed (elastically deformed), and continues to bias the contact end portion 30a toward the head portion 24a of the fixing screw 24. Accordingly, the elastic member 30 and fixing screw 24 continue to be in elastic contact with each other. As a result, the electrical connection between the fixing screw 24 and the frame 18 via the elastic member 30 is maintained.

When an object storing static electricity, such as a finger of a person, comes into contact with the head portion 24a of the fixing screw 24 exposed to the outside at the outer surface of the external member 12, electricity flows through the fixing screw 24. The electricity flowing through the fixing screw 24 flows into the elastic member 30 via the contact end portion 30a which is in elastic contact with the head portion 24a. Then, electricity in the elastic member 30 flows into the frame 18 which is in contact with the base portion 30c. That is, the frame 18 functions as a static eliminating member that eliminates electricity of the fixing screw 24 via the elastic member 30. As a result, electrostatic discharge from the fixing screw 24 to the nearby circuit board 16 is suppressed.

From the moment when the head portion 24a of the fixing screw 24 comes into contact with the contact end portion 30a of the elastic member 30, the rotation of the head portion 24a by the tool is transmitted to the elastic member 30. However, as illustrated in FIG. 6, since a plurality of positioning pins 12e of the external member 12 is engaged with the plurality of positioning holes 30e of the base portion 30c, the rotation of the elastic member 30 is restricted.

In addition, the contact end portion 30a of the elastic member 30 receives a force so as to be displaced in the rotation direction of the head portion 24a from the moment of contact with the head portion 24a of the fixing screw 24. In order to appropriately maintain the contact with the head portion 24a even when receiving such a force, as illustrated in FIG. 4, the one end 30d of the contact end portion 30a has a round corner (processed to be rounded).

According to the present embodiment as described above, in the electronic device 10 including the fixing screw 24 that is used without having a contact with the conductive member, electrostatic discharge from the fixing screw 24, for example, electrostatic discharge from the fixing screw 24 to the circuit board, 16 can be suppressed.

Although the embodiment of the present disclosure has been described above with reference to the above-described embodiment, the embodiment of the present disclosure is not limited thereto.

For example, in the above-described embodiment, as illustrated in FIG. 3, the elastic member 30 is in elastic contact with the head portion 24a of the fixing screw 24. This causes the electrical connection between the fixing screw 24 and the frame 18 via the elastic member 30 to be maintained. However, the embodiment of the present disclosure is not limited thereto.

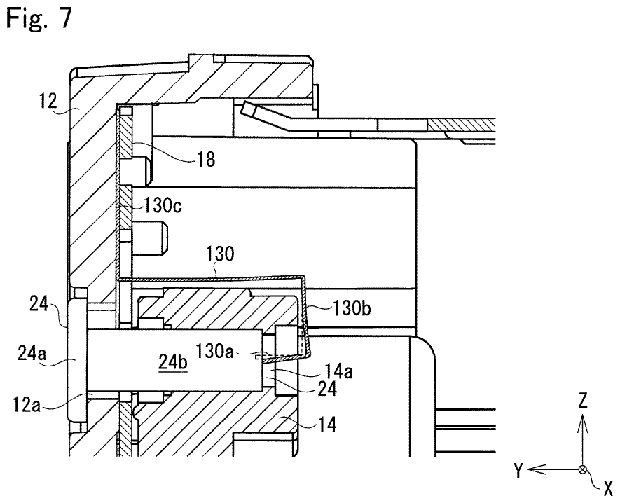

FIG. 7 is a partial cross-sectional view of a part of an electronic device according to another embodiment. Note that, in another embodiment illustrated in FIG. 7, components substantially the same as the components of the above-described embodiment are denoted by the same reference numerals.

As illustrated in FIG. 7, in the electronic device according to another embodiment, an elastic member 130 is in elastic contact with a fixing screw 24 in a first direction (Y-axis direction).

Specifically, the elastic member 130 includes a contact end portion 130a whose one end is in contact with the fixing screw 24, a cantilever portion 130b extending from the other end of the contact end portion 130a, and a base portion 130c that supports the cantilever portion 130b in a cantilever manner and is in contact with a frame 18. The contact end portion 130a is in elastic contact with a distal end of a male screw portion 24b of the fixing screw 24 in the first direction (Y-axis direction). Therefore, the contact end portion 130a enters a female screw hole 14a of an internal member 14 having a penetration hole shape.

Also in such another embodiment, similar to the above-described embodiment, electrostatic discharge from the fixing screw 24 can be suppressed.

In addition, in the above-described embodiment, as illustrated in FIG. 3, the elastic member 30 and the frame 18 that are in contact with each other and electrically connected to each other are separate members. Alternatively, the elastic member 30 and the frame 18 may be different parts of one conductive member.

Furthermore, in the above-described embodiment, as illustrated in FIGS. 1 and 2, a member electrically connected to the fixing screw 24 via the elastic member 30 is the frame 18 that supports the circuit board 16. However, the embodiment of the present disclosure is not limited thereto. When the electronic device includes a conductive member other than the frame 18, the fixing screw 24 may be electrically connected to the conductive member via an elastic member. That is, the member in contact with the elastic member may be any static eliminating member as long as it that can eliminate electricity of the fixing screw 24 via the elastic member.

Moreover, in the above-described embodiment, a fixing member that fixes the external member 12 to the internal member 14 is the fixing screw 24. However, the embodiment of the present disclosure is not limited thereto. The fixing member that fixes the external member 12 to the internal member 14 in the first direction may be, for example, a bolt, a rivet, or the like.

That is, in a broad sense, an electronic device according to the embodiment of the present disclosure includes: a non-conductive external member; a non-conductive internal member disposed on an inner side of the external member; a conductive fixing member that is exposed to an outside at an outer surface of the external member and fixes the external member to the internal member in a first direction; a conductive elastic member in elastic contact with the fixing member in the first direction; and a static eliminating member that is electrically connected to the elastic member and eliminates electricity of the fixing member via the elastic member.

As described above, the above-described embodiments have been described as examples of the technology in the present disclosure. To that end, the drawings and detailed description are provided. Therefore, the components described in the drawings and the detailed description may include not only components essential for solving the problem but also components that are not essential for solving the problem in order to exemplify the above-described technology. Therefore, it should not be immediately recognized that these non-essential components are essential based on the fact that these non-essential components are described in the drawings and the detailed description.

In addition, since the above-described embodiments are intended to exemplify the technology in the present disclosure, various changes, replacements, additions, omissions, and the like can be made within the scope of the claims or equivalents thereof.

The present disclosure is applicable to an electronic device including a fixing screw that is used without having a contact with a conductive member.

What is claimed is:

1. An electronic device comprising:
a non-conductive external member;
a non-conductive internal member disposed on an inner side of the external member;
a conductive fixing member that is exposed to an outside at an outer surface of the external member and fixes the external member to the internal member in a first direction;
a conductive elastic member in elastic contact with the fixing member in the first direction; and
a static eliminating member that is electrically connected to the elastic member and eliminates electricity of the fixing member via the elastic member.

2. The electronic device according to claim 1, wherein
the fixing member is a fixing screw including a head portion exposed to the outside, and a male screw portion extending from the head portion in the first direction,
the external member includes a through hole penetrating in the first direction and through which the male screw portion of the fixing screw passes, and
the internal member includes a female screw hole engaged with the male screw portion of the fixing screw.

3. The electronic device according to claim 2, wherein the elastic member enters the through hole of the external member and comes into contact with the head portion of the fixing screw in the first direction.

4. The electronic device according to claim 3, wherein the elastic member includes a contact end portion whose one end is in contact with the head portion of the fixing screw in the first direction, a cantilever portion extending from another end of the contact end portion in a second direction intersecting the first direction, and a base portion that supports the cantilever portion in a cantilever manner and is in contact with the static eliminating member.

5. The electronic device according to claim 2, wherein
the female screw hole of the internal member has a penetration hole shape, and
the elastic member enters the female screw hole or another penetration hole and comes into elastic contact with a distal end of the male screw portion of the fixing screw in the first direction.

6. The electronic device according to claim 1, wherein the static eliminating member is a metal frame that supports the internal member.

7. The electronic device according to claim 6, wherein
the frame supports a circuit board, and
a ground potential part of the circuit board is electrically connected to the frame.
